(19) United States
(12) Patent Application Publication
(10) Pub. No.: US 2019/0152206 A1
(43) Pub. Date: May 23, 2019

(54) POLY(PHENYLENE ETHER)-CONTAINING COMPOSITE AND LAMINATE PREPARED THEREFROM, AND METHOD OF FORMING COMPOSITE

(71) Applicant: SABIC GLOBAL TECHNOLOGIES B.V., Bergen op Zoom (NL)

(72) Inventors: Carolyn A. DEGONZAGUE, Albany, NY (US); Eylem TARKIN-TAS, Delmar, NY (US); Ying NA, Shanghai (CN)

(21) Appl. No.: 15/778,449

(22) PCT Filed: Nov. 22, 2016
(86) PCT No.: PCT/US2016/063314

§ 371 Date: May 23, 2018

Related U.S. Application Data
(60) Provisional application No. 62/259,724, filed on Nov. 25, 2015.

(51) Int. Cl. B32B 27/28; B32B 27/38; B32B 5/02; B32B 5/08; B32B 5/26; B32B 7/04; C08J 5/24

(52) U.S. Cl. CPC B32B 27/285; H05K 1/0353; B32B 27/38; B32B 5/024; B32B 5/08; B32B 5/26; B32B 7/04; C08J 5/24; B32B 2250/20; B32B 2255/02; B32B 2255/26; B32B 2260/023; B32B 2379/08; B32B 2315/08; B32B 2457/08; B32B 27/281

(57) ABSTRACT

A composite comprises a reinforcing fabric and an at least partially cured composition at least partially coating the reinforcing fabric, wherein the reinforcing fabric comprises first fibers wrapped with, woven with, or wrapped and woven with polyimide fibers, and the at least partially cured composition comprises the product of 30 to 70 weight percent of a poly(phenylene ether) having a number average molecular weight of 600 to 2000 AMU, 30 to 70 weight percent of a curable component, and a curing agent, wherein weight percent is based on the combined weight of poly(phenylene ether) and the curable component.

### BACKGROUND OF THE INVENTION

Increases in digital processing speeds demand printed circuit boards incorporating dielectric materials with lower dielectric constants and loss tangents. It has been shown that the incorporation of poly(phenylene ether) oligomers can decrease dielectric constants and loss tangents in epoxy and vinyl-based thermosets. See, e.g., U.S. Pat. No. 7,655,278 of Peters et al. (using hydroxy-diterminated poly(phenylene ether) oligomers in epoxy-based thermosets); and U.S. Pat. No. 6,352,782 of Yeager et al. (using methacrylate-terminated poly(phenylene ether) oligomers in vinyl-based thermosets). However, these methods have the disadvantage that their uncured compositions have high viscosity, which makes it more difficult to “wet” the reinforcing fabrics and avoid air bubbles.

There remains a need for dielectric materials exhibiting low viscosity in the uncured state, and low dielectric constants and loss tangents in the cured state.

### BRIEF SUMMARY OF EMBODIMENTS OF THE INVENTION

Described herein is a method of forming a composite, comprising at least partially coating a reinforcing fabric with a curable application composition and removing at least a portion of the solvent from the curable application composition-coated reinforcing fabric to form the composite. The reinforcing fabric comprises first fibers wrapped with, woven with, or wrapped and woven with polyimide fibers. The curable application composition comprises 30 to 70 weight percent of a solvent, 15 to 60 weight percent of a curable component, 5 to 40 weight percent of poly(phenylene ether) having a number average molecular weight of 600 to 2000 atomic mass units (AMU), and a curing agent, wherein weight percent is based on the combined weight of solvent, curable component, poly(phenylene ether) and curing agent.

Another embodiment is a composite comprising a reinforcing fabric and a curable composition at least partially coating the reinforcing fabric. The reinforcing fabric comprises first fibers wrapped with, woven with, or wrapped and woven with polyimide fibers. The curable composition comprises 30 to 70 weight percent of a poly(phenylene ether) having a number average molecular weight of 600 to 2000 AMU, 30 to 70 weight percent of a curable component, and a curing agent, wherein weight percent is based on the combined weight of the poly(phenylene ether) and curable component.

Another embodiment is a composite comprising a reinforcing fabric and an at least partially cured composition at least partially coating the reinforcing fabric. The reinforcing fabric comprises first fibers wrapped with, woven with, or wrapped and woven with polyimide fibers. The at least partially cured composition comprises the product of 30 to 70 weight percent of a poly(phenylene ether) having a number average molecular weight of 600 to 2000 AMU, 30 to 70 weight percent of a curable component, and a curing agent, wherein weight percent is based on the combined weight of the poly(phenylene ether) and curable component.

Another embodiment is a laminate comprising the product of laminating a plurality of prepregs, wherein each prepreg comprises a reinforcing fabric and an at least partially cured composition at least partially coating the reinforcing fabric. The reinforcing fabric comprises first fibers wrapped with, woven with, or wrapped and woven with polyimide fibers. The at least partially cured composition comprises the product of 30 to 70 weight percent of a poly(phenylene ether) having a number average molecular weight of 600 to 2000 AMU, 30 to 70 weight percent of a curable component, and a curing agent, wherein weight percent is based on the combined weight of the poly(phenylene ether) and curable component.

These and other embodiments are described in detail below.

### DETAILED DESCRIPTION OF THE INVENTION

It has been discovered that dielectric materials with low dielectric constants and loss tangents in the cured state can be obtained from a curable composition comprising poly(phenylene ether) and a reinforcing fabric comprising first fibers wrapped with, woven with, or wrapped and woven with polyimide fibers.

A method of forming a composite comprises at least partially coating a reinforcing fabric with a curable application composition and removing at least a portion of the solvent from the curable application composition-coated reinforcing fabric to form the composite. The composite comprises the reinforcing fabric and a curable composition. The curable composition results from solvent removed from the curable application composition. The solvent can be removed by evaporation at the desired temperature either at atmospheric pressure or under vacuum. Exemplary conditions include 20 to 30° C. at atmospheric pressure.

The reinforcing fabric comprises first fibers wrapped with, woven with, or wrapped and woven with polyimide fibers. The first fibers comprise glass fibers, carbon fibers, aromatic polyamide fibers, or a combination comprising two or more of the foregoing. In any embodiment described herein the polyimide may be a polyetherimide. In some embodiments the reinforcing fabric is woven from first fibers wrapped in polyimide fibers. In some embodiments the reinforcing fabric is woven from glass fibers wrapped in polyimide fibers. It is also contemplated that the reinforcing fabric can be woven from two types of first fibers wrapped in polyimide fibers. For example, the reinforcing fabric can be woven from glass fibers wrapped in polyimide fibers and carbon fibers wrapped in polyimide fibers. It is also contemplated that a first fiber wrapped with a polyimide fiber can be co-woven with an additional type of first fiber. For example, a glass fiber wrapped with polyimide can be co-woven with a carbon fiber. It is also contemplated that a first fiber wrapped with a polyimide fiber can be co-woven with polyimide fiber. For example, a glass fiber wrapped with a polyimide fiber can be co-woven with a polyimide fiber.

In some embodiments the reinforcing fabric is co-woven with first fibers and polyimide fibers. The first fibers can be used for at least a portion of the weft and the polyimide fibers can be used for at least a portion of the warp, the first fibers can be used for at least a portion of the warp and the polyimide fibers used for at least a portion of the weft, or the first and polyimide fibers can be comingled. In some embodiments the co-woven reinforcement fabric comprises glass fibers and polyimide fibers. In some embodiments the polyimide fiber can be polyetherimide fibers. Additional reinforcing fabrics include co-woven structures comprising at least two types of first fibers, including glass fiber-carbon fiber and carbon fiber-aromatic polyimide (aramid) fiber and polyimide fiber. For example, the reinforcing fabric can be co-woven from glass fibers, carbon fibers and polyimide fibers.

While there is a range of potential combinations, the reinforcing fabric comprises, based on the total weight of the fiber, 40 to 90 weight percent of combined first fibers and 10 to 60 weight percent of polyimide fibers. Within these ranges the reinforcing fabric comprises, 45 to 80 weight percent of combined first fibers and 20 to 55 weight percent of polyimide fibers, or, more specifically, 45 to 75 weight percent of combined first fibers and 25 to 55 weight percent of polyimide fibers.

The curable application composition comprises a solvent. The poly(phenylene ether) of the curable composition is soluble in the solvent at a temperature below the atmospheric boiling point of the solvent but the polyimide fibers have little or no solubility in the solvent at the conditions of at least partial curing as discussed below. Exemplary solvents include acetone, methyl ethyl ketone, methyl isobutyl ketone, or a combination of two or more of the foregoing solvents. These solvents are relatively volatile, which facilitates solvent removal from composites at least partially coated with the curable composition. In some embodiments, the solvent comprises acetone. In some embodiments, the solvent comprises methyl ethyl ketone. In some embodiments, the solvent comprises methyl isobutyl ketone.

The curable application composition comprises the solvent in an amount of 30 to 70 weight percent, based on the combined weight of solvent, curable component, poly(phenylene ether) and curing agent. Within this range, the solvent amount can be 40 to 60 weight percent, specifically 45 to 55 weight percent.

In addition to the solvent, the curable application composition comprises a curable component. The curable component is at least partially soluble in the solvent at a temperature below the atmospheric boiling point of the solvent. The curable component comprises an epoxy resin, cyanate ester resin, benzoxazine resin, vinyl resin, esterimide resin, silicone resin, or a combination of two or more of the foregoing curable components. The term “resin” as used herein refers to oligomers and monomers that are reactive to form an at least partially cured material. Examples of epoxy resins include bisphenol A epoxy resins, glycidylamine epoxy resins, novolak epoxy resins, modified bisphenol A epoxy resins, alicyclic epoxy resins; and epoxy resins derived from Bisphenol F, resorcinol, tetramethyl biphenol, tetrahydroxyphenylethane, polyalcohols, polyglycols, and the like. The epoxy resins can comprise difunctional epoxy compounds, polyfunctional epoxy compounds or a combination thereof. As used herein, the term difunctional epoxy compound refers to a compound having two epoxy groups per molecule. The term polyfunctional epoxy compound refers to a compound having more than two epoxy groups per molecule. Examples of vinyl resins include triallyl cyanurate, triallyl isocyanurate, styrene, butadiene, vinyl esters and combinations of two or more of the foregoing. In some embodiments, the curable component comprises cyanate ester resin, vinyl resin, difunctional epoxy compounds, cresol novolac epoxy resin, or a combination of two or more of the foregoing. In some embodiments, the curable component is a bisphenol A epoxy resin, which is a reaction product of bisphenol A and epichlorohydrin.

The curable application composition includes the curable component in an amount of 15 to 60 weight percent, based on the total weight of the composition. Within this range, the amount of the curable component can be 20 to 55 weight percent, specifically 25 to 50 weight percent.

The curable composition comprises the curable component in an amount of 30 to 70 weight percent, based on the combined weight of poly(phenylene ether) and curable component. Within this range the amount of curable component can be 40 to 60 weight percent, specifically 45 to 55 weight percent.

In addition to the solvent and the curable component, the curable application composition comprises a poly(phenylene ether). The poly(phenylene ether) has a number average molecular weight of 600 to 2000 atomic mass units (AMU). Within this range, the number average molecular weight can be 700 to 1500 AMU, specifically 700 to 1200 AMU. The poly(phenylene ether) also has an average of 1.5 to 3 hydroxyl groups per molecule. Within this range, the average hydroxyl groups per molecule can be 1.7 to 2.5, specifically 1.7 to 2.2.

In some embodiments, the poly(phenylene ether) comprises a hydroxy-diterminated poly(phenylene ether) having the structure

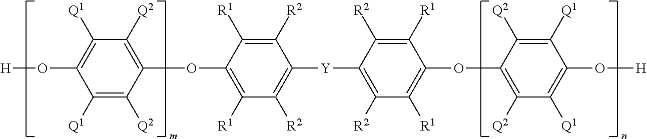

wherein each occurrence of Q¹ is independently halogen, C₁-C₁₂ hydrocarbylthio, C₁-C₁₂ hydrocarbyloxy, C₂-C₁₂ halohydrocarbyloxy wherein at least two carbon atoms separate the halogen and oxygen atoms, or unsubstituted or substituted C₁-C₁₂ hydrocarbyl provided that the hydrocarbyl group is not tertiary hydrocarbyl; each occurrence of Q² is independently hydrogen, halogen, C₁-C₁₂ hydrocarbylthio, C₁-C₁₂ hydrocarbyloxy, C₂-C₁₂ halohydrocarbyloxy wherein at least two carbon atoms separate the halogen and oxygen atoms, or unsubstituted or substituted C₁-C₁₂ hydrocarbyl provided that the hydrocarbyl group is not tertiary hydrocarbyl; each occurrence of R¹ and R² is independently hydrogen, halogen, C₁-C₁₂ hydrocarbylthio, C₁-C₁₂ hydrocarbyloxy, C₂-C₁₂ halohydrocarbyloxy wherein at least two carbon atoms separate the halogen and oxygen atoms, or unsubstituted or substituted C₁-C₁₂ hydrocarbyl provided that the hydrocarbyl group is not tertiary hydrocarbyl; m and n are independently 0 to 20, provided that the sum of m and n is at least 3; and Y is selected from

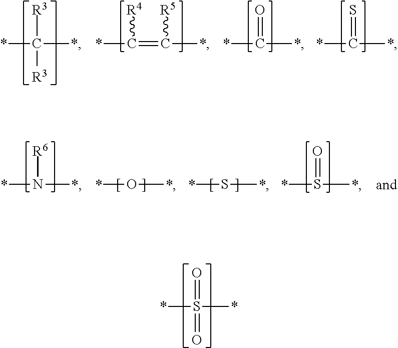

wherein each occurrence of R³-R⁶ is independently hydrogen or C₁-C₁₂ hydrocarbyl. The hydroxy-diterminated poly(phenylene ether) can be prepared by copolymerizing a dihydric phenol having the structure

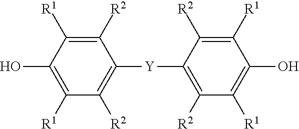

and a monohydric phenol having the structure

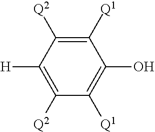

wherein R¹, R², Q¹, and Q² are defined above. As used herein, the term “hydrocarbyl”, whether used by itself, or as a prefix, suffix, or fragment of another term, refers to a residue that contains only carbon and hydrogen unless it is specifically identified as “substituted hydrocarbyl”. The hydrocarbyl residue can be aliphatic or aromatic, straight-chain, cyclic, bicyclic, branched, saturated, or unsaturated. It can also contain combinations of aliphatic, aromatic, straight chain, cyclic, bicyclic, branched, saturated, and unsaturated hydrocarbon moieties. When the hydrocarbyl residue is described as substituted, it can contain heteroatoms in addition to carbon and hydrogen.

In some embodiments, the poly(phenylene ether) comprises a hydroxy-diterminated poly(phenylene ether) having the structure

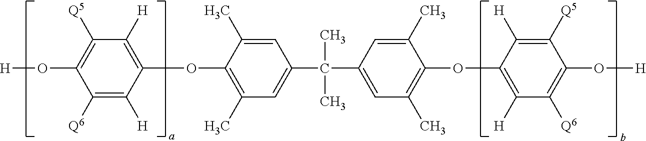

wherein each occurrence of Q⁵ and Q⁶ is independently methyl or di-n-butylaminomethyl, and each occurrence of a and b is independently 0 to 20, provided that the sum of a and b is at least 3. In these embodiments, the poly(phenylene ether) can be prepared by copolymerizing 2,2-bis(3,5-dimethyl-4-hydroxyphenyl)propane and 2,6-dimethylphenol in the presence of a catalyst comprising di-n-butylamine.

The curable application composition comprises the poly(phenylene ether) in an amount of 5 to 40 weight percent, based on the total weight of the composition. Within this range, the poly(phenylene ether) amount can be 5 to 30 weight percent, specifically 5 to 20 weight percent.

The curable composition comprises poly(phenylene ether) in an amount of 30 to 70 weight percent, based on the combined weight of poly(phenylene ether) and curable component. Within this range the amount of poly(phenylene ether) can be 40 to 60 weight percent, specifically 45 to 55 weight percent.

In addition to the solvent, the curable component, and the poly(phenylene ether), the curable application composition can, optionally, include a curing agent for the curable component. A person skilled in the art can determine a suitable curing agent and amount based on the identity and amount of the curable component present in the composition. Suitable curing agents for cyanate ester resins, include, for example, cobalt complexes, copper complexes, manganese complexes, zinc complexes, and aluminum complexes such as aluminum acetylacetonate. Suitable curing agents for radical cured vinyl resin such as triallyl cyanurate, triallyl isocyanurate, styrene and vinyl esters include, for example, organic peroxides. Suitable curing agents for butadienes include, for example, sulfur systems, organic peroxides, urethane crosslinkers, metallic oxides, and acetoxysilane. Curing agents for epoxy resins include latent cationic cure catalysts, phenolic hardeners, amine compounds, anhydrides, copper (II) salts of aliphatic carboxylic acids, copper (II) salts of aromatic carboxylic acids, aluminum (III) salts of aliphatic carboxylic acids, aluminum (III) salts of aromatic carboxylic acids, copper (II) β-diketonates, aluminum (III) β-diketonates, borontrifluoride-trialkylamine complexes, and combinations thereof. Suitable curing agents for esterimide resins include, for example, organic peroxides. Curing agents for silicone resins include tin complexes and platinum complexes.

The composition can, optionally, further include one or more additives selected from the group consisting of dyes, pigments, colorants, antioxidants, heat stabilizers, light stabilizers, plasticizers, lubricants, flow modifiers, drip retardants, flame retardants, antiblocking agents, antistatic agents, flow-promoting agents, processing aids, substrate adhesion agents, toughening agents, low-profile additives, stress-relief additives, air release additives, wetting and dispersing agents, surface and leveling agents, and combinations thereof. Air release additives promote the release of entrapped air prior to the processing of the thermoset system. They promote air bubble coalescence. In general, air release additives fall into two categories—silicone based and non-silicone based. Dispersing agents act to move and separate agglomerated particles to smaller particles. Wetting and dispersing additives can be used in filled resin systems in order to wet out the particle surfaces, accelerate dispersion, reduce viscosity and dispersion time, increase dispersion quality, lower viscosity, allow higher filler loading, increase the filler load without influencing the viscosity, prevent re-agglomeration, and prevent sedimentation. All these effects will lead to increased homogeneity of the finished part. A preferred class of wetting and dispersing agents is nonionic fluorosurfactants. Nonionic fluorosurfactants are commercially available as, for example, NOVEC nonionic polymeric fluorosurfactants from 3M, ZONYL nonionic fluorosurfactants from DuPont, and CAPSTONE short-chain nonionic fluorosurfactants from DuPont. Surface and leveling agents can reduce surface tension at the resin-substrate interface and improve wetting and flow characteristics, prevent fisheyes, craters, surface defects, and improve leveling. Surface and leveling agents are sometimes used in combination with air release additives. Nonionic fluorosurfactants, such as NOVEC nonionic polymeric fluorosurfactants from 3M, are excellent wetting, levelling and flow control agents for a variety of waterborne, solvent-borne, high-solids, and radiation curable organic polymer coating systems.

When present, additives are generally used in an amount of 0.1 to 5 weight percent, based on the total weight of the curable composition. Within this range, the total amount of additives can be 0.5 to 3 weight percent, specifically 0.5 to 2 weight percent.

In an embodiment of the curable application composition, the solvent comprises methyl ethyl ketone; the curable component comprises a difunctional epoxy compound, a polyfunctional epoxy compound, or a combination thereof; the poly(phenylene ether) has a number average molecular weight of 600 to 2000 atomic mass units; and the composition comprises 40 to 60 weight percent of the solvent, 25 to 50 weight percent of the curable component, and 1 to 30 weight percent of the poly(phenylene ether) and weight percent is based on the combined weight of solvent, curable component, poly(phenylene ether), and curing agent.

The method of forming a composite can, optionally, further comprise at least partially curing the composite to form a prepreg. Conditions for at least partially curing the curable composition can be determined by the skilled person by accounting for factors including the identity and amount of the curable component, and the identity and amount of the curing agent. For example, when the curable component is a bisphenol A epoxy resin present in the curable composition at 50 weight percent, and the curing agent is 2-ethyl-4-methyl imidazole present at 1 part by weight per 100 parts by weight of the curable component, partial curing can be effected by exposing the curable composition to 3 to 5 minutes at 140° C.

All of the variations described above in the context of the curable composition and the reinforcing fabric apply as well to the method of forming a composite, to the composite itself and to laminates and prepregs formed from the composite.

In an embodiment of the method, the reinforcing fabric comprises glass fiber and polyimide fiber; the solvent comprises methyl ethyl ketone; the curable component comprises a difunctional epoxy compound, a polyfunctional epoxy compound, or a combination thereof; the poly(phenylene ether) has a number average molecular weight of 600 to 2000 atomic mass units; and the composition comprises 40 to 60 weight percent of the solvent, 25 to 50 weight percent of the curable component, and 1 to 30 weight percent of the poly(phenylene ether) and weight percent is based on the combined weight of solvent, curable component, poly(phenylene ether), and curing agent.

Another embodiment is a laminate comprising the product of laminating a plurality of prepregs, wherein each prepreg comprises a reinforcing fabric, and an at least partially cured resin at least partially coating the reinforcing fabric. The at least partially cured composition comprises, based on the total weight of the composition, the product of 30 to 70 weight percent of a poly(phenylene ether) having a number average molecular weight of 600 to 2000 AMU, 30 to 70 weight percent of a curable component, and a curing agent, wherein weight percent is based on the combined weight of poly(phenylene ether) and curable component. In the context of “laminating a plurality of prepregs”, the word “plurality” means at least two. The number of prepregs used to form a laminate can be, for example, 3 to 12. It will also be understood that the process of laminating includes further curing the partially cured composition of the prepreg. For example, in laminating can be conducted for 30 minutes to 5 hours, at a temperature of 150 to 200° C., at a pressure of 10 to 100 megapascals.

Embodiment 1: A composite comprising a reinforcing fabric and a curable composition at least partially coating the reinforcing fabric, wherein the reinforcing fabric comprises first fibers wrapped with, woven with, or wrapped and woven with polyimide fibers, the curable composition comprises 30 to 70 weight percent of a poly(phenylene ether) having a number average molecular weight of 600 to 2000 AMU, 30 to 70 weight percent of a curable component, and a curing agent, and further wherein the first fibers comprise glass fibers, carbon fibers, aromatic polyamide fibers, or a combination comprising two or more of the foregoing and weight percent is based on the combined weight of poly(phenylene ether) and curable component.

Embodiment 2: A composite comprising a reinforcing fabric and an at least partially cured composition at least partially coating the reinforcing fabric, wherein the reinforcing fabric comprises first fibers wrapped with, woven with, or wrapped and woven with polyimide fibers, and the at least partially cured composition comprises, based on the total weight of the composition, the product of 30 to 70 weight percent of a poly(phenylene ether) having a number average molecular weight of 600 to 2000 AMU, 30 to 70 weight percent of a curable component, and a curing agent, and further wherein the first fibers comprise glass fibers, carbon fibers, aromatic polyamide fibers, or a combination comprising two or more of the foregoing and weight percent is based on the combined weight of poly(phenylene ether) and curable component.

Embodiment 3: The composite of Embodiment 1 or 2, wherein the first fibers comprise glass fibers.

Embodiment 4: The composite of Embodiment 3, wherein the reinforcing fabric is woven from glass fibers wrapped with polyimide fibers.

Embodiment 5: The composite of Embodiment 4, wherein the reinforcing fabric is woven from glass fibers and polyimide fibers.

Embodiment 6: The composite of any of Embodiments 1 to 5, wherein the reinforcing fabric comprises, based on the total weight of the fibers, 40 to 90 weight percent of combined first fibers and 10 to 60 weight percent of combined second fibers.

Embodiment 7: The composite of any of Embodiments 1 to 6, wherein the curable component comprises an epoxy resin, cyanate ester resin, benzoxazine resin, vinyl resin, esterimide resin, silicone resin, or a combination of two or more of the foregoing curable components.

Embodiment 8: The composite of any of Embodiment 1 to 7, wherein the curable component comprises a bisphenol A epoxy resin.

Embodiment 9: The composite of Embodiment 8, wherein the curing agent is 2-ethyl-4-methyl imidazole.

Embodiment 10: A method of forming a the composite of any of Embodiments 1 to 9, comprising at least partially coating a reinforcing fabric with a curable application composition and removing at least a portion of solvent from the curable composition-coated reinforcing fabric to form the composite, wherein the curable application composition comprises 30 to 70 weight percent of solvent, 15 to 60 weight percent of the curable component, 5 to 40 weight percent of poly(phenylene ether) having a number average molecular weight of 600 to 2000 atomic mass units (AMU), and the curing agent and weight percent is based on the combined weight of solvent, curable component, poly(phenylene ether) and curing agent.

Embodiment 11: The method of Embodiment 10, wherein the solvent comprises acetone, methyl ethyl ketone, methyl isobutyl ketone, or a combination of two or more of the foregoing solvents.

Embodiment 12: The method of Embodiment 10 or 11, wherein the solvent is removed at a temperature of 20 to 30° C. and atmospheric pressure.

Embodiment 13: The method of any one of Embodiments 10 to 13, wherein the method further comprises at least partially curing the composite to form a prepreg.

Embodiment 14: A laminate comprising the product of laminating a plurality of prepregs according to Embodiment 13.

The invention is further illustrated by the following non-limiting examples.

### EXAMPLES

Components used to prepare compositions are summarized in Table 1.

TABLE 1

| Compo- | |
|---|---|
| nent | Description |
| MEK | Methyl ethyl ketone, CAS Reg. No. 78-93-3; obtained from |
| | Fisher Scientific. |
| Acetone | Acetone, CAS Reg. No. 67-64-1, Obtained from Fisher |
| | Scientific |
| BPA | Bisphenol A diglycidyl ether, CAS Reg. No. 1675-54-3, |
| Epoxy | having an epoxy equivalent weight of 185-192 daltons; |
| | obtained as D.E.R 332 from Dow. |
| 2,4-EMI | 2-Ethyl-4-methylimidazole, CAS Reg. No. 931-36-2, obtained |
| | from Fisher Scientific. |
| PPE | A copolymer of 2,6-dimethylphenol and 2,2-bis(3,5-dimethyl- |
| | 4-hydroxyphenyl)propane, CAS Reg. No. 1012321-47-9, |
| | having a hydroxyl equivalent weight of 924 grams per |
| | equivalent, an average of 1.92 hydroxyl groups per molecule, |
| | and an intrinsic viscosity of 0.09 deciliters per gram as |
| | measured at 25° C. in chloroform; available as NORYL ™ |
| | SA90 Resin from SABIC Innovative Plastics. |
| E-glass | E-glass cloth having a metric count of 87 × 67 per 5 |
| cloth | centimeters, yarn 9 68 1 × 0 9 68 1 × 0 warp × fill, |
| | thickness of 0.173 millimeters, and a weight of 203.4 gram/ |
| | meter²; obtained as Fabric Style 7628 from BGF Industries, |
| | Inc. |
| Hybrid | E glass fibers woven with polyetherimide fibers. The fabric |
| Fabric | comprises 50 weight percent polyetherimide fiber and 50 |
| | weight percent glass fiber, based on the total weight of |
| | the material. |

For comparative examples using E glass fabric without poly(phenylene ether), methyl ethyl ketone and bisphenol A diglycidyl ether are completely mixed to a homogeneous solution. The material is cooled to 30° C. and the 2-ethyl-4-methylimidazole is added. Once dissolved the mixture is transferred to a pan and the reinforcing fabric is submerged in the resin mixture. Once properly wetted, the coated fabric is air dried for 30 minutes and partially cured for 3 minutes at 140° C. to form a prepreg. The prepregs are layered with copper foil on the top and bottom of the stack in a polytetrafluoroethylene coated aluminum foil pouch and cured for 3 hours at 200° C. on a laminate press.

For comparative examples using E glass fabric and inventive examples using hybrid fabric the poly(phenylene ether) is dissolved in methyl ethyl ketone heated to 50° C. Once the poly(phenylene ether) is dissolved, bisphenol A diglycidyl ether is added and stirred until dissolved. The mixture is cooled to 30° C. and the 2-ethyl-4-methylimidazole is added. The mixture is transferred to a pan and the reinforcing fabric is submerged in the resin mixture. Once properly wetted, the coated fabric is air dried for 30 minutes and partially cured for 3 minutes at 140° C. to form a prepreg. The prepregs are layered with copper foil on the top and bottom of the stack in a polytetrafluoroethylene coated aluminum foil pouch and cured for 3 hours at 200° C. on a laminate press.

Dielectric constants (Dk) and dissipation factors (Df) of the laminates are measured at 23° C., according to IPC-TM-650-2.5.5.9 using a Hewlett Packard Parallel Plate RF impedance/material analyzer 1 megahertz to 1.8 gigahertz, equipped with a Hewlett Packard Dielectric Material test fixture model 16453A. Test laminates had the dimensions 2.5 by 2.5 centimeters. The laminates are conditioned at 23° C. for at least 24 hours before testing.

Dielectric measurements are conducted using a capacitance method, sweeping a range of frequencies when DC voltage was applied to the dielectric materials. The applied voltage was 0.2 millivolt to 1 volt at the frequency range of 1 megahertz to 1 gigahertz. Values for dielectric constants (Dk, relative permittivity) and loss tangent (Df, dissipation factor) at a frequency of 1 gigahertz are recorded. The formulations are summarized in Table 2 and the results are summarized in Table 3.

TABLE 2

| | CE1 | CE2 | CE3 | Ex. 1 |
|---|---|---|---|---|
| | Reinforcing fabric | | | |
| | E-glass cloth | E-glass cloth | E-glass cloth | Hybrid Fabric |
| BPA Epoxy | 50 g | 50 g | 25 g | 40 g |
| PPE | — | — | 25 g | 25 g |
| 2,4-EMI | 1 g | 2 g | 1 g | 1 g |
| MEK | 50 g | — | 50 g | 50 g |
| Acetone | — | 50 g | — | — |

TABLE 3

| | Weight % | | | Weight | Dk at | Df at |
|---|---|---|---|---|---|---|
| | Epoxy | Polyimide | PPE | % glass | 1 GHz | 1 GHz |
| CE1 | 56.3 | — | — | 43.7 | 3.4992 | 0.0139 |
| CE2 | 46.0 | — | — | 54.0 | 3.8408 | 0.0147 |
| CE3 | 29.9 | — | 29.9 | 40.2 | 3.3192 | 0.0086 |
| Ex. 1 | 17.1 | 32.9 | 17.1 | 32.9 | 2.0597 | 0.0043 |

Examples 1 shows a decrease on the dielectric constant and dissipation factor.

In general, the invention may alternately comprise, consist of, or consist essentially of, any appropriate components herein disclosed. The invention may additionally, or alternatively, be formulated so as to be devoid, or substantially free, of any components, materials, ingredients, adjuvants or species used in the prior art compositions or that are otherwise not necessary to the achievement of the function and/or objectives of the present invention.

All ranges disclosed herein are inclusive of the endpoints, and the endpoints are independently combinable with each other (e.g., ranges of “up to 25 wt. %, or, more specifically, 5 wt. % to 20 wt. %”, is inclusive of the endpoints and all intermediate values of the ranges of “5 wt. % to 25 wt. %,” etc.). “Combination” is inclusive of blends, mixtures, alloys, reaction products, and the like. Furthermore, the terms “first,” “second,” and the like, herein do not denote any order, quantity, or importance, but rather are used to denote one element from another. The terms “a” and “an” and “the” herein do not denote a limitation of quantity, and are to be construed to cover both the singular and the plural, unless otherwise indicated herein or clearly contradicted by context. The suffix “(s)” as used herein is intended to include both the singular and the plural of the term that it modifies, thereby including one or more of that term (e.g., the film(s) includes one or more films). Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A composite comprising a reinforcing fabric and a curable composition at least partially coating the reinforcing fabric, wherein the reinforcing fabric comprises first fibers wrapped with, woven with, or wrapped and woven with polyimide fibers, the curable composition comprises 30 to 70 weight percent of a poly(phenylene ether) having a number average molecular weight of 600 to 2000 AMU, 30 to 70 weight percent of a curable component, and a curing agent, weight percent is based on the combined weight of the curable component and poly(phenylene ether), and further wherein the first fibers comprise glass fibers, carbon fibers, aromatic polyamide fibers, or a combination comprising two or more of the foregoing.

2. (canceled)

3. The composite of claim 1, wherein the first fibers comprise E glass fibers.

4. The composite of claim 3, wherein the reinforcing fabric is woven from glass fibers wrapped with polyimide fibers.

5. The composite of claim 4, wherein the reinforcing fabric is woven from glass fibers and polyimide fibers.

6. The composite of claim 1, wherein the reinforcing fabric comprises, based on the total weight of the fabric, 40 to 90 weight percent of combined first fibers and 10 to 60 weight percent of polyimide fibers.

7. The composite of claim 1, wherein the curable component comprises an epoxy resin, cyanate ester resin, benzoxazine resin, vinyl resin, esterimide resin, silicone resin, or a combination of two or more of the foregoing curable components.

8. The composite of claim 1, wherein the curable component comprises a bisphenol A epoxy resin.

9. The composite of claim 8, wherein the curing agent is 2-ethyl-4-methyl imidazole.

10. A method of forming a the composite of claim 1, comprising at least partially coating the reinforcing fabric with a curable application composition and removing at least a portion of solvent from the curable application composition-coated reinforcing fabric to form the composite, wherein the curable application composition comprises 30 to 70 weight percent of a solvent, 15 to 60 weight percent of the curable component, 5 to 40 weight percent of poly(phenylene ether) having a number average molecular weight of 600 to 2000 atomic mass units (AMU), and the curing agent and weight percent is based on the combined weight of solvent, curable component, poly(phenylene ether) and curing agent.

11. The method of claim 10, wherein the solvent comprises acetone, methyl ethyl ketone, methyl isobutyl ketone, or a combination of two or more of the foregoing solvents.

12. The method of claim 10, wherein the solvent is removed at a temperature of 20 to 30° C. and atmospheric pressure.

13. The method of claim 10, wherein the method further comprises at least partially curing the composite to form a prepreg.

14. A laminate comprising the product of laminating a plurality of prepregs according to claim 13.

15. The composite of claim 1, wherein the first fibers comprise E glass fibers and the polyimide fiber is polyetherimide fiber.

16. (canceled)

17. The composite of claim 15 wherein the curable composition is partially cured.

18. The composite of claim 1, wherein the curable composition is partially cured.
